(19) United States
(12) Patent Application Publication
(10) Pub. No.: US 2023/0238218 A1
(43) Pub. Date: Jul. 27, 2023

(54) SEPARATED GAS INLET STRUCTURE FOR BLOCKING PLASMA BACKFLOW

(71) Applicant: JIANGSU LEUVEN INSTRUMENTS CO. LTD, Xuzhou (CN)

(72) Inventors: Haiyang LIU, Xuzhou (CN); Xiaobo LIU, Xuzhou (CN); Dongdong HU, Xuzhou (CN); Jun ZHANG, Xuzhou (CN); Shiran CHENG, Xuzhou (CN); Song GUO, Xuzhou (CN); Na LI, Xuzhou (CN); Kaidong XU, Xuzhou (CN)

(21) Appl. No.: 17/999,427

(22) PCT Filed: May 19, 2021
(86) PCT No.: PCT/CN2021/094609

§ 371 Date: Nov. 21, 2022

(30) Foreign Application Priority Data
May 21, 2020 (CN) 202010435707.0

(51) Int. Cl. H01J 37/32

(52) U.S. Cl. CPC H01J 37/3244; H01J 2237/334

(57) ABSTRACT

A separated gas inlet structure for blocking plasma backflow includes a gas inlet flange and an upper gas inlet nozzle and a lower gas inlet nozzle made of ceramic materials. The upper gas inlet nozzle is coaxially nested or stacked at the top of the lower gas inlet nozzle; a broken line type gas inlet channel is in the upper gas inlet nozzle and the lower gas inlet nozzle and the gas inlet channel includes an upper axial channel, a radial channel, a lower axial channel and a gas outlet; the radial channel or the lower axial channel is at a mounting matching part of the upper gas inlet nozzle and the lower gas inlet nozzle; and the top of the lower axial channel points to a bottom wall surface of the upper gas inlet nozzle.

### TECHNICAL FIELD

The present disclosure relates to the field of semiconductor integrated circuit manufacturing, and in particular to a separated gas inlet structure for blocking plasma backflow.

### BACKGROUND

In the process of semiconductor integrated circuit manufacturing, etching is one of the most important processes, and plasma etching is one of the commonly used etching methods, which commonly takes place in the vacuum reaction chamber. The vacuum reaction chamber includes an electrostatic adsorption chuck configured to function as carrying adsorption wafers, RF loads and cooling wafers. At present, in the manufacturing process of semiconductor devices, the electrostatic adsorption chuck is commonly placed on the base in the middle of the reaction chamber. The wafer is located on the upper surface of the electrostatic adsorption chuck. RF is applied to the electrode on the top of the base to enable the reaction gas introduced into the reaction chamber to form plasma for processing the wafer.

In the process of etching some non-volatile metal materials, the plasma accelerates to reach the surface of the metal material under the action of bias voltage, and the metal particles splashed from the etched material surface will attach to all exposed surfaces in the cavity, including the inner wall of the cavity and the coupling window on the top of the cavity, resulting in pollution. In order to solve the pollution, it is necessary to inject cleaning gas into the reaction chamber, and load RF power on the top to ionize the cleaning gas for taking away these pollution particles. Since the cavity is grounded during the whole cleaning process and the top coupling window is made of insulating material, the RF power loaded on the top excites the plasma during the cleaning process, and the active plasma will clean the grounded cavity, however, the cleaning effect on the medium window is almost no, and as time goes on, the pollutants will be stacked more seriously, resulting in a phenomenon of the deposition falling off and polluting the wafer.

In order to clean the coupling window thoroughly, electrostatic shielding can be used. Faraday shielding can be used in the plasma treatment chamber to reduce the erosion of plasma on the cavity materials. The existing technology is to connect the middle ceramic gas inlet nozzle with Faraday, and connect the RF at the same time, so that both the coupling window and the middle ceramic gas inlet nozzle can be cleaned thoroughly through the cleaning process. However, when the RF power is gradually loaded, the cleaning gas enters the cavity through the gas inlet channel, ionizes in the cavity under the action of the RF power supply, and forms a plasma flow, and at the same time, the plasma flow will return to the gas inlet channel through the gas inlet hole. The gas inlet channel is too close to the RF power point, resulting in ignition in the air inlet channel, damaging the air inlet guide, and being unusable.

As illustrated in FIG. 1, the electrostatic adsorption chuck 2 is located in the center of the reaction chamber 1, the wafer 3 is located on the upper surface of the electrostatic adsorption chuck 2, the chamber cover 4 is located directly above the reaction chamber 1, and the coupling window 5 is placed on the chamber cover 4, the central area of the coupling window 5 is empty and provided with a central gas inlet device.

At present, in the prior art, as illustrated in FIG. 2, the central gas inlet device includes an gas inlet nozzle 50, a central gas inlet guide body 51 and an gas inlet flange 52, wherein the gas inlet flange 52 is made of metal and connected with the upper RF matcher 8. As illustrated in FIG. 3, the structure of the central gas inlet guide body 51 has gas guide channels 511, 512 and 513 that are upper vertical holes, middle radial holes and lower vertical holes connected with each other from top to bottom.

Coils 6 are arranged on the upper surface of the coupling window outside the central gas inlet device and also connected to the RF matcher 8.

When the etching process is carried out in the reaction chamber, the line connecting the RF matcher to the coils is conductive, the process gas enters through the inlet flange 52, reaches the inside of the gas inlet nozzle 50 through the gas guide channels 511, 512 and 513 on the central gas inlet guide body 51, and then enters the inside of the reaction chamber through the gas outlet to form plasma and etch the wafer 3.

When the cleaning process needs to be carried out, the RF matcher 8 disconnects with the coils 6 and opens the path connected to the inlet flange 52. At the same time, the cleaning gas enters through the inlet flange 52 and also enters into the reaction chamber along the direction 100, forming an ionized cleaning plasma gas flow inside the reaction chamber to clean the inner area and upper area of the reaction chamber. However, since the gas inlet flange 52 is connected to the high-power cleaning RF, and the gas guide channel 513 on the central gas inlet guide body 51 is vertical, the plasma formed in the reaction chamber backflows to the inside of the gas guide channel 513 through the gas outlet at the bottom of the gas inlet nozzle 50, while the gas inlet flange 52 is closely connected with the upper part of the central gas inlet guide body 51, such that the gas guide channel 513 is conductive to the gas inlet flange 52, and the gas discharges in this area, forming a high charge inside the gas guide channel 513 and burning out the gas inlet guide body.

The improvement solution of the prior art for this problem is as illustrated in FIG. 4. The gas inlet channels 801, 802 are transferred to the inside of the central gas inlet guide body 80. This structure design solves the problem of plasma backflow, gas discharge in the gas inlet channel, high charge formation in the gas inlet channel, and burning out the gas inlet guide body to a certain extent. However, this structure has the following shortcomings.

1. The central gas inlet guide body is arranged inside the gas inlet nozzle, and there is an assembly clearance between the outer wall surface of the central gas inlet guide body located above the gas inlet channel 802 and the inner wall surface of the gas inlet nozzle; however, the plasma backflow gas after backflow through the gas inlet channel 803 will pass through the assembly clearance to contact the gas inlet flange, so as to discharge in the assembly clearance and burn out the central gas inlet guide body. Therefore, the smaller the assembly clearance, the better, which puts forward higher processing requirements for the central gas inlet guide body and the gas inlet nozzle.

2. When plastic is selected as the material of the central gas inlet guide body, the central gas inlet guide body will be exposed to the strong oxidizing and reducing plasma environment in the case of the plasma backflow, especially the strong oxidizing and reducing plasma backflow, and the plastic material itself will be continuously eroded, release particles, and pollute the reaction chamber, thereby causing damage to the process.

3. When ceramic is selected as the material of the central gas inlet guide body, the assembly clearance between the central gas inlet guide body and gas inlet nozzle is required to be as small as possible, however, the central gas inlet guide body made of ceramic will expand in a high temperature environment, resulting in the crack of the gas inlet nozzle. The specific performance is as follows: the approximate formula for calculating the linear length of alumina ceramics after heating is L2=L1*T*σ, where the expansion coefficient is σ=7E-6/K, T is the temperature, L1 is the size in a normal temperature, and L2 is the size after thermal expansion. In the 400 k environment, the size of the ceramic with a diameter of 40 mm increases by about 0.1 mm after expansion. When the assembly clearance between the gas inlet nozzle and the central gas inlet guide body is greater than 0.05 mm, the electrons will directly face the RF through the clearance, resulting in plasma backflow and burning out the gas inlet nozzle. When the assembly clearance is less than 0.05 mm, there is a risk that the gas inlet nozzle will be damaged due to thermal expansion.

### SUMMARY

The technical problems to be solved by the present disclosure are to provide a separated gas inlet structure for blocking plasma backflow in view of the shortcomings in the prior art. In the separated gas inlet structure for blocking plasma backflow, the ceramic gas inlet nozzle is set as two separate parts instead of the traditional central gas inlet guide body, which can effectively solve the technical problems of plasma backflow in the prior art, resulting in gas discharge in the gas inlet channel, forming high charges in the gas inlet channel and burning out the gas inlet guide body, while facilitating installation, processing and maintenance.

To solve the above technical problems, the technical solutions adopted by the present disclosure are as follows.

Provided is a separated gas inlet structure for blocking plasma backflow, the structure comprises a gas inlet flange, an upper gas inlet nozzle and a lower gas inlet nozzle that both are made of ceramic materials.

A top of the upper gas inlet nozzle extends into a bottom of the gas inlet flange. The upper gas inlet nozzle is coaxially nested or coaxially stacked at the top of the lower gas inlet nozzle. Both the top of the upper gas inlet nozzle and the top of the lower gas inlet nozzle are lapped on a coupling window.

A broken line type gas inlet channel is provided in the upper gas inlet nozzle and the lower gas inlet nozzle, and the gas inlet channel includes an upper axial channel, a radial channel, a lower axial channel and a gas outlet.

A top of the upper axial channel is in communication with the gas inlet channel of the gas inlet flange, a bottom of the upper axial channel is in communication with the radial channel.

The radial channel or the lower axial channel is positioned at a mounting matching part of the upper gas inlet nozzle and the lower gas inlet nozzle.

The top of the lower axial channel is in communication with the radial channel and points to a bottom wall surface of the upper gas inlet nozzle. The bottom of the lower axial channel is in communication with the gas outlet, the gas outlet points to a vacuum reaction chamber obliquely.

The upper gas inlet nozzle is coaxially nested at the top of the lower gas inlet nozzle.

A bottom edge of the lower gas inlet nozzle is provided with a plurality of gas outlets circumferentially.

The lower axial channel is a plurality of axial edge grooves, which are arranged on a bottom outer wall surface of the upper gas inlet nozzle nested and matched with the lower gas inlet nozzle. The radial channel is radial holes with the same number as the axial edge grooves, all the radial holes are built in the middle of the upper gas inlet nozzle circumferentially; each radial hole is arranged along the radial direction of the upper gas inlet nozzle; an outer end of each radial hole is in communication with a top of the corresponding lower axial channel.

The upper axial channel is axial straight non-through holes with the same number as the axial edge grooves, a bottom end of each axial straight non-through hole is in communication with the inner end of the corresponding radial hole, and a top end of each axial straight non-through hole is in communication with the gas inlet channel of the gas inlet flange.

The lower axial channel is in communication with the gas outlet through a uniform-gas channel, the uniform-gas channel is arranged on the outer wall surface of the lower gas inlet nozzle below the lower axial channel.

A nesting clearance between the upper gas inlet nozzle and the lower gas inlet nozzle is greater than 0.1 mm.

The upper gas inlet nozzle is respectively sealed with a bottom of the gas inlet flange and a side wall surface of the coupling window through a sealing ring.

The upper gas inlet nozzle is coaxially stacked at the top of the lower gas inlet nozzle.

The center of the upper gas inlet nozzle is provided with an upper axial channel, the upper axial channel is a plurality of axial through holes uniformly arranged along the circumferential direction with respect to the central axis of the upper gas inlet nozzle.

The radial channel is set at the top center of the lower gas inlet nozzle; the gas outlet is arranged at the bottom edge of the lower gas inlet nozzle circumferentially.

The lower axial channel includes the axial straight non-through holes with the same number as the gas outlets; all axial straight non-through holes are built in the edge of the lower gas inlet nozzle circumferentially, and are configured to communicate the radial channel and the gas outlet.

The radial channel is a circular radial uniform-gas channel.

The upper gas inlet nozzle is respectively sealed with the bottom of the gas inlet flange and the side wall surface of the coupling window through the sealing ring.

The top of the upper gas inlet nozzle and the top of the lower gas inlet nozzle are both provided with a lap flange lapped on the coupling window, respectively; the height of the radial channel is lower than the lap flange at the top of the lower gas inlet nozzle.

The present disclosure has the following beneficial effects.

1. In the present disclosure, the ceramic gas inlet nozzle is set into two separate parts of the upper gas inlet nozzle and the lower gas inlet nozzle creatively, instead of the traditional central gas inlet guide body, which can effectively solve the technical problems of plasma backflow in the prior art, resulting in the gas discharge in the gas inlet channel, forming high charges in the gas inlet channel, and burning out the gas inlet guide body, while facilitating the installation, processing and maintenance

2. The design of the broken line type gas inlet channel provided in the upper gas inlet nozzle and the lower gas inlet nozzle can avoid the close communication between the gas inlet channel and the RF components, and avoid the sufficient channel distance in the vertical direction for electronic movement ignition.

3. Since the top of the lower axial channel points to the bottom wall surface of the upper gas inlet nozzle, that is, a physical blockage is formed. Therefore, when the plasma gas flow inside the reaction chamber backflow through the gas outlet, after passing through the lower axial channel and hitting the physical wall at the bottom of the upper gas inlet nozzle above the lower axial channel, the energy in the electrons will gradually disappear with the collision. That is to say, the area closest to the gas inlet flange with RF power is insulated and uncharged, and the path in conduction with the high-power components cannot be formed, thus protecting the upper gas inlet nozzle from the damage of high heat and high RF. Furthermore, since both the upper gas inlet nozzle and the lower gas inlet nozzle are made of ceramic materials, they are not eroded by strong oxidizing and reducing plasma, thus avoiding the generation of particles and polluting the wafer.

4. Since the gas inlet nozzle adopts a separate structure, and the radial channel or the lower axial channel is located at the mounting matching part of the upper gas inlet nozzle and the lower gas inlet nozzle; Therefore, the fit clearance between the upper gas inlet nozzle and the lower gas inlet nozzle can be increased, so as to prevent the upper gas inlet nozzle from expanding and damaging the lower gas inlet nozzle due to the heat generated during plasma backflow. In addition, the processing requirements for the gas inlet nozzle are not high, which is convenient for popularization.

5. The height of the radial channel is lower than the lap flange at the top of the lower gas inlet nozzle, and the lap flange can seal the gas flow in the radial channel. In addition, when the plasma gas flow inside the reaction chamber backflows through the gas outlet, it will not contact the mounting matching parts of the upper gas inlet nozzle and the lower gas inlet nozzle after passing through the lower axial channel.

### BRIEF DESCRIPTION OF THE DRAWINGS

FIG. 1 illustrates a structure diagram of a plasma etching system in the prior art.

FIG. 2 illustrates a structure diagram of a central gas inlet device in the plasma etching system of the prior art.

FIG. 3 illustrates a structure diagram of a central gas inlet guide body in the plasma etching system of the prior art.

FIG. 4 illustrates a structure diagram of the improved central gas inlet guide body in FIG. 3 by the prior art.

FIG. 5 illustrates the first embodiment of a separated gas inlet structure for blocking plasma backflow in the present disclosure.

FIG. 6 illustrates the first embodiment of an upper gas inlet nozzle in the present disclosure.

FIG. 7 illustrates the first embodiment of a lower gas inlet nozzle in the present disclosure.

FIG. 8 illustrates the second embodiment of the separated gas inlet structure for blocking plasma backflow in the present disclosure.

FIG. 9 illustrates the second embodiment of the upper gas inlet nozzle in the present disclosure.

FIG. 10 illustrates the second embodiment of the lower gas inlet nozzle in the present disclosure.

FIG. 11 illustrates a layout of an axial through hole and an axial straight non-through hole in the gas inlet nozzle in the second embodiment.

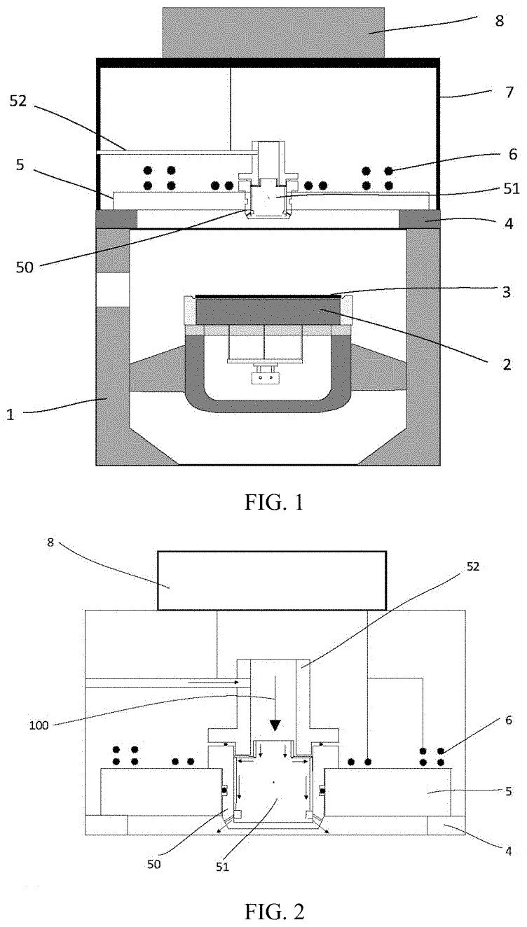

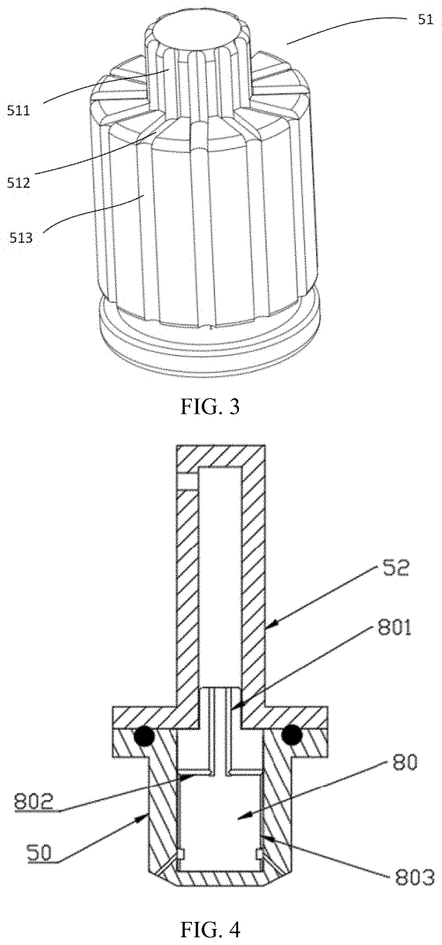

Provided in FIGS. 1 to 4 are as follows.

1. Reaction chamber; 2. Electrostatic adsorption chuck; 3. Wafer; 4. Chamber cover; 5. Coupling window; 6. Coil; 7. Shielding box; 8. RF matcher ; 50. Gas inlet nozzle; 51, 80. Central gas inlet guide body; 511, 801. Upper vertical holes; 512, 802. Middle radial holes; 513, 803. Lower vertical holes; 52. Gas inlet flange.

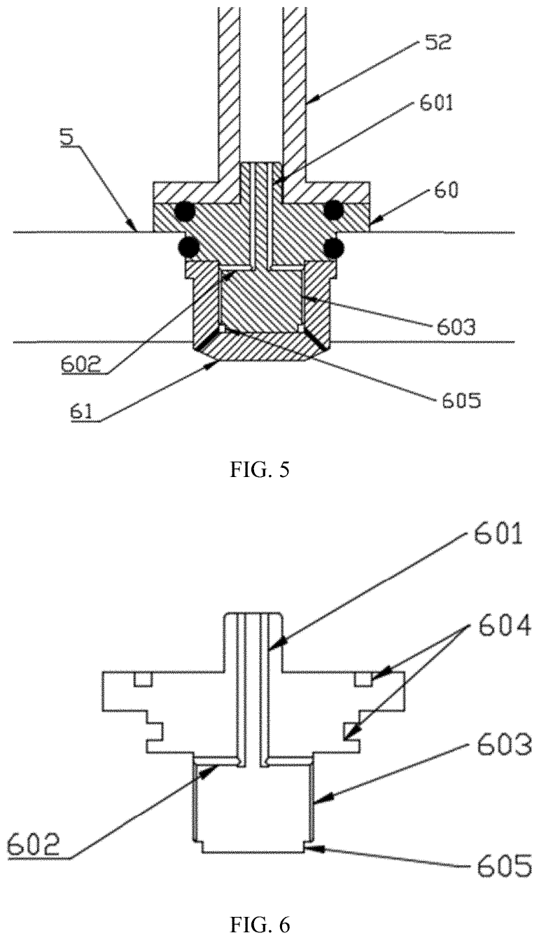

Provided in FIGS. 5 to 7 are as follows.

60. Upper gas inlet nozzle; 601. Axial straight non-through hole; 602. Radial hole; 603. Axial edge groove; 604. Sealing groove; 605. Uniform-gas channel; 61. Lower gas inlet nozzle; 611. Gas outlet.

Provided in FIGS. 8 to 11 are as follows.

90. Upper gas inlet nozzle; 901. Axial non-through hole; 902. Sealing groove; 91. Lower gas inlet nozzle; 911. Radial uniform-gas channel; 912. Axial straight non-through hole; 913. Gas outlet; 914. Axial through-hole distribution ring; 915. Axial straight non-through hole distribution ring.

### DETAILED DESCRIPTION OF THE EMBODIMENTS

The present disclosure will be further described in detail below in combination with the accompanying drawings and specific preferred implementations.

In the description of the present disclosure, it should be understood that the terms such as “left side”, “right side”, “upper”, “lower” indicate the orientation or position relationship based on the orientation or position relationship illustrated in the drawings, which is only for the convenience of describing the present disclosure and simplifying the description, rather than indicating or implying that the device or element referred to must have a specific orientation, be constructed and operated in a specific orientation. The “first”, “second” and the like do not indicate the importance of the parts, and therefore cannot be understood as a limitation of the present disclosure.

The present disclosure adopts the following two preferred embodiments for detailed description. The specific size or quantity used in the embodiments is only for an illustration of the technical solutions, and does not limit the protection scope of the present disclosure.

Embodiment 1

As illustrated in FIG. 5, provided is a separated gas inlet structure for blocking plasma backflow. The structure comprises a gas inlet flange 52, an upper gas inlet nozzle 60 and a lower gas inlet nozzle 61 that both are made of ceramic materials.

The top of the upper gas inlet nozzle is preferably provided with an upper boss, and the bottom of the upper gas inlet nozzle is preferably provided with a lower boss. The upper boss extends into the bottom of the gas inlet flange. The design of the upper boss utilizes the structure of the upper gas inlet nozzle itself to enable the gas inlet channel and the gas inlet flange 52 to be RF insulated.

The upper gas inlet nozzle is coaxially nested at the lower gas inlet nozzle. The top of the upper gas inlet nozzle and the top of the lower gas inlet nozzle are both provided with a lap flange lapped on the coupling window, respectively.

The upper gas inlet nozzle is respectively sealed with the bottom of the gas inlet flange and the side wall surface of the coupling window through a sealing ring. The specific preferred setting is that: the upper surface of the lap flange of the upper gas inlet nozzle and the outer wall surface of the upper gas inlet nozzle located below the lap flange are provided with a sealing groove 604 as illustrated in FIG. 6, respectively, and each sealing groove is embedded with a sealing ring.

A broken line type gas inlet channel is provided in the upper gas inlet nozzle and the lower gas inlet nozzle. The broken line design of the gas inlet channel is to avoid the close communication between the gas inlet channel and the RF components, and to avoid the sufficient channel distance in the vertical direction for the electronic movement ignition.

The gas inlet channel includes an upper axial channel, a radial channel, a lower axial channel and a gas outlet.

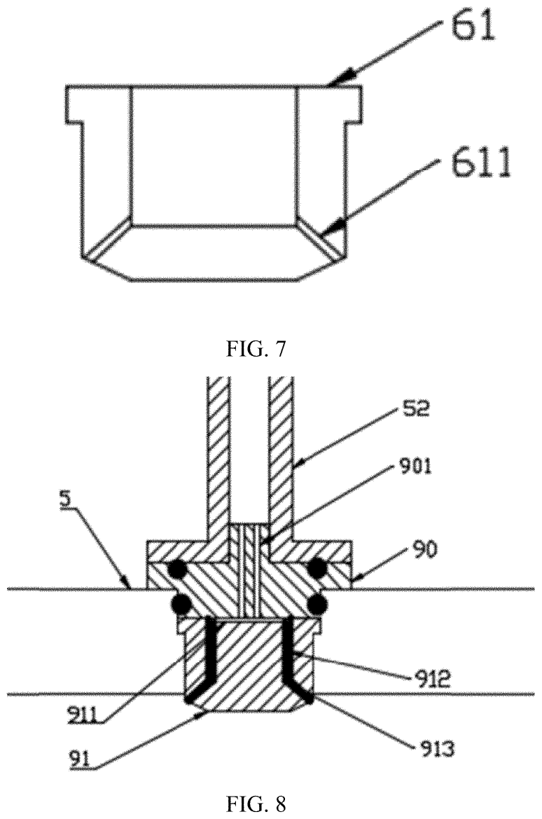

As illustrated in FIG. 7, the gas outlet 611 is preferably arranged circumferentially along the bottom edge of the lower gas inlet nozzle 61, and each gas outlet is inclined.

The upper axial channel is preferably arranged along the axial direction of the upper gas inlet nozzle, the top of the upper axial channel is in communication with the gas inlet channel of the gas inlet flange, the bottom of the upper axial channel is in communication with the radial channel.

As illustrated in FIG. 5 and FIG. 6, the upper axial channel is preferably axial straight non-through holes 601 with the same number as axial edge grooves, the bottom end of each axial straight non-through hole is in communication with the inner end of the corresponding radial hole, and the top end of each axial straight non-through hole is in communication with the gas inlet channel of the gas inlet flange.

The height of the radial channel is lower than the lap flange at the top of the lower gas inlet nozzle. The lap flange is capable of sealing the gas flow in the radial channel. In addition, when the plasma gas flow inside the reaction chamber reflows through the gas outlet, the plasma gas flow will not contact the mounting matching part of the upper gas inlet nozzle and the lower gas inlet nozzle after passing through the lower axial channel.

The radial channel is preferably radial holes 602 with the same number as axial edge grooves, all radial holes are built in the middle of the upper gas inlet nozzle circumferentially; each radial hole is arranged along the radial direction of the upper gas inlet nozzle; the outer end of each radial hole is in communication with the top of the corresponding lower axial channel.

The lower axial channel is positioned at the mounting matching part of the upper gas inlet nozzle and the lower gas inlet nozzle.

The lower axial channel is preferably arranged along the axial direction of the lower gas inlet nozzle, and the top of the lower axial channel is in communication with the radial channel and points to the bottom wall surface of the upper gas inlet nozzle. The bottom of the lower axial channel is in communication with the gas outlet, the gas outlet points to the vacuum reaction chamber obliquely.

The lower axial channel is preferably a plurality of axial edge grooves 603, which are arranged on the bottom outer wall surface (that is, the outer wall surface of the lower boss) of the upper gas inlet nozzle nested and matched with the lower gas inlet nozzle. The lower axial channel is preferably in communication with the gas outlet through the uniform-gas channel 605, the uniform-gas channel is arranged on the outer wall surface of the lower gas inlet nozzle located below the lower axial channel.

The nesting clearance between the upper gas inlet nozzle and the lower gas inlet nozzle may be greater than 0.1 mm, which can effectively solve the technical problems of plasma backflow in the prior art, resulting in the gas discharge in the gas inlet channel, forming high charges in the gas inlet channel, and burning out the gas inlet guide body, prevent the upper gas inlet nozzle from expanding and damaging the lower gas inlet nozzle due to the heat generated during plasma backflow. In addition, the processing requirements for the gas inlet nozzle are not high, which is convenient for popularization.

Further, the diameter of the axial edge groove 603 is preferably different from that of the axial straight non-through hole 601, the axial edge groove 603 and the axial straight non-through hole 601 will be faced directly in the vertical direction, and the specific analysis is shown in Embodiment 2.

The working principle of cleaning is as follows: during the cleaning process is conducted in the system, the cleaning gas is introduced from the gas inlet flange 52, flows through the gas holes 601, 602 and 603 on the upper gas inlet nozzle 60, and is eventually discharged from the gas outlet 611 at the bottom of the lower gas inlet nozzle 61 after being uniformed by 605. When the plasma gas flow inside the reaction chamber reflows through the gas outlet, the plasma gas flow enters the axial edge groove 603 through the gas inlet channel. Since the upper part of the axial edge groove 603 is physically blocked, the plasma gas flow will hit the physical wall on the upper part of the axial edge groove 603 at this position, and the energy in the electrons will gradually disappear with the collision, that is, the area closest to the gas inlet flange 52 with RF power is insulated and uncharged, and the path in conduction with the high-power components cannot be formed, thus protecting the upper gas inlet nozzle 60 from the damage of high heat and high RF. Since both the upper gas inlet nozzle 60 and the lower gas inlet nozzle 61 are made of ceramic materials, they are not eroded by strong oxidizing and reducing plasma, thus avoiding the generation of particles and polluting the wafer. Due to the design on the structure and material of the upper gas inlet nozzle 60, the fit clearance between the position where the axial edge groove 603 is located and the lower gas inlet nozzle 61 can be expanded, so as to prevent the upper gas inlet nozzle from expanding and damaging the lower gas inlet nozzle 61 due to the heat generated during plasma backflow.

Embodiment 2

As illustrated in FIG. 8, provided is a separated gas inlet structure for blocking plasma backflow. The structure comprises a gas inlet flange 52, an upper gas inlet nozzle 90 and a lower gas inlet nozzle 91 that both are made of ceramic materials.

The top of the upper gas inlet nozzle is preferably provided with an upper boss. The upper boss extends into the bottom of the gas inlet flange. The design of the upper boss utilizes the structure of the upper gas inlet nozzle itself to enable the gas inlet channel and the gas inlet flange 52 to be RF insulated.

The bottom of the upper gas inlet nozzle is a plane, preferably coaxially stacked at the top of the lower gas inlet nozzle.

The top of the upper gas inlet nozzle and the top of the lower gas inlet nozzle are both provided with a lap flange lapped on the coupling window.

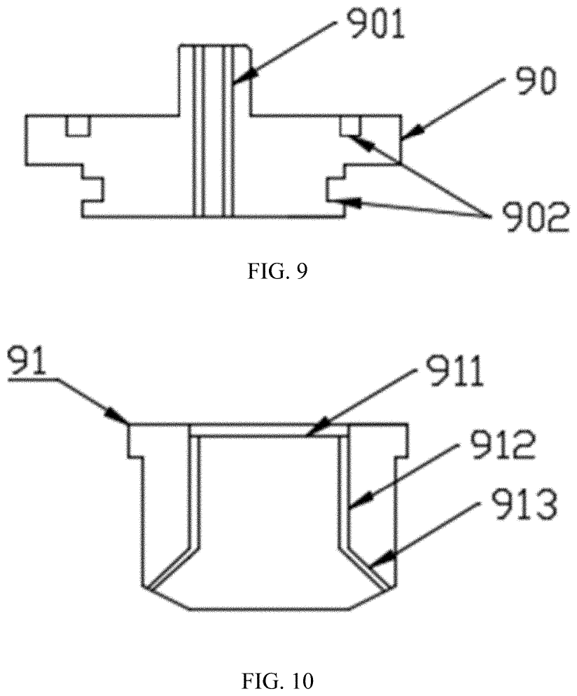

The upper gas inlet nozzle is respectively sealed with the bottom of the gas inlet flange and the side wall surface of the coupling window through a sealing ring. The preferred setting is specifically as follows: the upper surface of the lap flange of the upper gas inlet nozzle and the outer wall surface of the upper gas inlet nozzle located below the lap flange are provided with a sealing groove 902 as illustrated in FIG. 9, respectively, and each sealing groove is embedded with a sealing ring.

A broken line type gas inlet channel is provided in the upper gas inlet nozzle and the lower gas inlet nozzle. The design principle of the broken line is the same as above.

The gas inlet channel includes an upper axial channel, a radial channel, a lower axial channel and a gas outlet.

As illustrated in FIG. 8 and FIG. 9, the center of the upper gas inlet nozzle is provided with an upper axial channel, the upper axial channel is preferably a plurality of axial through holes 901 uniformly arranged along the circumferential direction with respect to the central axis of the upper gas inlet nozzle. Each axial through hole 901 is arranged along the axial direction of the upper gas inlet nozzle and throughly arranged in the upper gas inlet nozzle.

As illustrated in FIG. 10, the radial channel is arranged at the top center of the lower gas inlet nozzle, preferably a circular radial uniform-gas channel 911. That is, the radial channel is located at the mounting matching part of the upper gas inlet nozzle and the lower gas inlet nozzle.

Further, the height of the radial channel is lower than the lap flange at the top of the lower gas inlet nozzle, and the design principle is the same as Embodiment 1.

The gas outlet 913 is arranged circumferentially along the bottom edge of the lower gas inlet nozzle.

The lower axial channel includes axial straight non-through holes 912 with the same number as gas outlets; all axial straight non-through holes are built in the edge of the lower gas inlet nozzle circumferentially, and are configured to communicate the radial channel with the gas outlet. The top of the axial straight non-through hole 912 points to the bottom wall surface of the upper gas inlet nozzle.

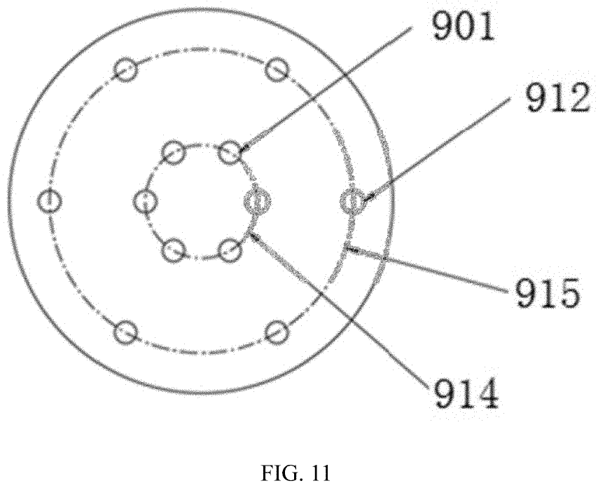

As illustrated in FIG. 11, the distribution diameter of the axial straight non-through hole 912 is preferably different from that of the axial through hole 901 in the upper gas inlet nozzle 90, that is to say, the diameter of the axial straight non-through hole distribution ring 915 is different from that of the axial through hole distribution ring 914. When the two diameters are the same, the axial straight non-through hole distribution ring 915 and the axial through hole distribution ring 914 will face directly with each other in the vertical direction, so that the vertical movement of the electrons will not be blocked, thereby preventing the energy in the electrons from disappearing gradually with the collision, on the contrary, the existence of a large vertical space enables the electrons to move violently, which will stimulate plasma in the gas inlet channel and damage the gas inlet nozzle.

Further, the radius difference between the axial straight non-through hole distribution ring 915 and the axial through hole distribution ring 914 should preferably be greater than or equal to the maximum of the diameters of the axial straight non-through holes 912 and the axial through holes 901, so that the axial straight non-through holes 912 and the axial through holes 901 will not directly face with each other in the vertical direction.

The working principle of cleaning is that: during the cleaning process is conducted in the system, the cleaning gas is introduced from the gas inlet flange 52, flows through the axial through hole 901 on the upper gas inlet nozzle 90, and is eventually discharged from the axial straight non-through hole 912 and the gas outlet 913 at the bottom after being uniformed through the radial uniform-gas channel 911 formed together with the lower gas inlet nozzle 91.

When the plasma gas flow inside the reaction chamber reflows through the gas outlet, the plasma gas flow enters the axial straight non-through hole 912 through the gas inlet channel. Since the upper part of the axial straight non-through hole 912 is physically blocked, the plasma gas flow will hit the physical wall on the upper part of the axial straight non-through hole 912 at this position, and the energy in the electrons will gradually disappear with the collision, that is, the area closest to the gas inlet flange 52 with RF power is insulated and uncharged, and the path in conduction with the high-power components cannot be formed, thus protecting the upper gas inlet nozzle 90 and the lower gas inlet nozzle 91 from the damage of high heat and high RF. Since both the upper gas inlet nozzle 90 and the lower gas inlet nozzle 91 are made of ceramic materials, they are not eroded by strong oxidizing and reducing plasma, thus avoiding the generation of particles and polluting the wafer. There is no clearance between the upper and lower parts of the gas inlet nozzle, thereby preventing the upper gas inlet nozzle 90 from expanding and damaging the lower gas inlet nozzle 91 due to the heat generated during plasma backflow.

By designing the gas inlet nozzle into an upper and lower part structure and the gas inlet channel into a broken line or bow shape, the present disclosure can reduce the plasma backflow in the cavity and prevent the backflow gas from contacting the high-power RF components, thus avoiding the close communication between the gas channel and the RF components, preventing the gas channel in the vertical direction from being sufficient for electronic movement ignition to damage the inlet structure, and preventing the strong oxidizing and reducing plasma from eroding the gas inlet device to generate particles and pollute the wafer.

Although the preferred embodiments of the present disclosure are described in detail above, the present disclosure is not limited to the specific details of the above implementations. A variety of equivalent transformations can be made to the technical solutions of the present disclosure within the scope of the technical concepts of the present disclosure, and these equivalent transformations all belong to the protection scope of the present disclosure.

What is claimed is:

1. A separated gas inlet structure for blocking plasma backflow, wherein the structure comprises a gas inlet flange, an upper gas inlet nozzle and a lower gas inlet nozzle that both are made of ceramic materials;
a top of the upper gas inlet nozzle extends into a bottom of the gas inlet flange; the upper gas inlet nozzle is coaxially nested or coaxially stacked at a top of the lower gas inlet nozzle, both the top of the upper gas inlet nozzle and the top of the lower gas inlet nozzle are lapped on a coupling window;
a broken line type gas inlet channel is provided in the upper gas inlet nozzle and the lower gas inlet nozzle, and the gas inlet channel includes an upper axial channel, a radial channel, a lower axial channel and a gas outlet;
a top of the upper axial channel is in communication with the gas inlet channel of the gas inlet flange, a bottom of the upper axial channel is in communication with the radial channel;
the radial channel or the lower axial channel is positioned at a mounting matching part of the upper gas inlet nozzle and the lower gas inlet nozzle; and
a top of the lower axial channel is in communication with the radial channel and points to a bottom wall surface of the upper gas inlet nozzle; the bottom of the lower axial channel is in communication with the gas outlet, the gas outlet points to a vacuum reaction chamber obliquely.

2. The separated gas inlet structure for blocking plasma backflow according to claim 1, wherein the upper gas inlet nozzle is coaxially nested at the top of the lower gas inlet nozzle;
a bottom edge of the lower gas inlet nozzle is provided with a plurality of gas outlets circumferentially;
the lower axial channel is a plurality of axial edge grooves, which are arranged on a bottom outer wall surface of the upper gas inlet nozzle nested and matched with the lower gas inlet nozzle;
the radial channel is radial holes with a same number as the axial edge grooves, all radial holes are built in a middle of the upper gas inlet nozzle circumferentially; each radial hole is arranged along a radial direction of the upper gas inlet nozzle; an outer end of each radial hole is in communication with a top of a corresponding lower axial channel;
the upper axial channel is axial straight non-through holes with the same number as the axial edge grooves; a bottom end of each axial straight non-through hole is in communication with an inner end of a corresponding radial hole, and a top end of each axial straight non-through hole is in communication with the gas inlet channel of the gas inlet flange.

3. The separated gas inlet structure for blocking plasma backflow according to claim 2, wherein the lower axial channel is in communication with the gas outlet through a uniform-gas channel, the uniform-gas channel is arranged on the outer wall surface of the lower gas inlet nozzle located below the lower axial channel.

4. The separated gas inlet structure for blocking plasma backflow according to claim 2, wherein a nesting clearance between the upper gas inlet nozzle and the lower gas inlet nozzle is greater than 0.1 mm.

5. The separated gas inlet structure for blocking plasma backflow according to claim 2, wherein the upper gas inlet nozzle is respectively sealed with a bottom of the gas inlet flange and a side wall surface of the coupling window through a sealing ring.

6. The separated gas inlet structure for blocking plasma backflow according to claim 1, wherein the upper gas inlet nozzle is coaxially stacked at the top of the lower gas inlet nozzle;
a center of the upper gas inlet nozzle is provided with an upper axial channel, the upper axial channel is a plurality of axial through holes uniformly arranged along a circumferential direction with respect to a central axis of the upper gas inlet nozzle;
the radial channel is arranged at a top center of the lower gas inlet nozzle;
the gas outlet is arranged at the bottom edge of the lower gas inlet nozzle circumferentially;
the lower axial channel includes the axial straight non-through holes with the same number as the gas outlets; all axial straight non-through holes are built in an edge of the lower gas inlet nozzle circumferentially, and are configured to communicate the radial channel with the gas outlet.

7. The separated gas inlet structure for blocking plasma backflow according to claim 6, wherein the radial channel is a circular radial uniform-gas channel.

8. The separated gas inlet structure for blocking plasma backflow according to claim 6, wherein the upper gas inlet nozzle is respectively sealed with the bottom of the gas inlet flange and the side wall surface of the coupling window through the sealing ring.

9. The separated gas inlet structure for blocking plasma backflow according to claim 1, the top of the upper gas inlet nozzle and the top of the lower gas inlet nozzle are both provided with a lap flange lapped on the coupling window, respectively; a height of the radial channel is lower than the lap flange at the top of the lower gas inlet nozzle.
